(19) United States
(12) Patent Application Publication
(10) Pub. No.: US 2015/0069444 A1
(43) Pub. Date: Mar. 12, 2015

(54) LIGHT EMITTING DIODE

(71) Applicant: Seoul Viosys Co., Ltd., Ansan-si (KR)

(72) Inventors: Jong Hyeon CHAE, Ansan-si (KR); Jong Min Jang, Ansan-si (KR); Joon Sup Lee, Ansan-si (KR); Won Young Roh, Ansan-si (KR); Daewoong Suh, Ansan-si (KR); Hyun A Kim, Ansan-si (KR); Yu Dae Han, Ansan-si (KR); Min Woo Kang, Ansan-si (KR); Seon Min Bae, Ansan-si (KR)

(21) Appl. No.: 14/481,351

(22) Filed: Sep. 9, 2014

(30) Foreign Application Priority Data
Sep. 10, 2013 (KR) 10-2013-0108326
Sep. 27, 2013 (KR) 10-2013-0115500

(51) Int. Cl. H01L 33/60; H01L 33/32; H01L 33/40; H01L 33/62

(52) U.S. Cl. CPC H01L 33/60; H01L 33/62; H01L 33/32; H01L 33/405
USPC 257/98

(57) ABSTRACT

A light emitting diode and a method of fabricating the same, the light emitting diode including a substrate, a semiconductor layer formed on one surface of the substrate, and an anti-reflection element formed on the other surface of the substrate and including a nano-pattern. The anti-reflection element is interposed between the substrate and air.

### CROSS-REFERENCE TO RELATED APPLICATIONS

This application claims priority from and the benefit of Korean Patent Applications Nos. 10-2013-0108326, filed on Sep. 10, 2013, and 10-2013-0115500, filed on Sep. 27, 2013, which are hereby incorporated by reference for all purposes as if fully set forth herein.

### BACKGROUND FIELD

Aspects of the present invention relate to a light emitting diode and a method of fabricating the same, and more particularly, to a light emitting diode having improved light extraction efficiency and a method of fabricating the same.

### DESCRIPTION OF THE BACKGROUND

In general, gallium nitride light emitting diodes are fabricated by growing gallium nitride semiconductor layers on a sapphire substrate. Particularly, a patterned sapphire substrate (PSS) is mainly used as a growth substrate to improve light extraction efficiency. Patterns between a gallium nitride substrate and the sapphire substrate change a path along which light generated in an active layer travels, thereby reducing light loss due to total internal reflection.

However, some of light generated in the active layer can be totally reflected at an interface between the substrate and air due to a difference in index of refraction and thus, is lost within the semiconductor layers. Particularly, since the sapphire substrate has an index of refraction about 1.7 and air has an index of refraction 1.0 with respect to light at a wavelength of 450 nm, there is a relatively large difference in the index of refraction therebetween. Accordingly, total internal reflection is likely to occur at the interface between the substrate and air.

The above information disclosed in this Background section is only for enhancement of understanding of the background of the invention and therefore it may contain information that does not form any part of the prior art nor what the prior art may suggest to a person of ordinary skill in the art.

### SUMMARY

Aspects of the present invention provide a light emitting diode, which can reduce light loss within the light emitting diode while improving light extraction efficiency, and a method of fabricating the same.

In addition, aspects of the present invention provide a light emitting diode, which includes an anti-reflection element interposed between a substrate and air to reduce total internal is reflection of light travelling from a semiconductor stack to air through the substrate, thereby improving light extraction efficiency, and a method of fabricating the same.

Additional features of the invention will be set forth in the description which follows, and in part will be apparent from the description, or may be learned by practice of the invention.

In accordance with one aspect of the present invention, a light emitting diode includes: a substrate; a semiconductor layer formed on one surface of the substrate; and anti-reflection element formed on the other surface of the substrate, wherein the anti-reflection elements include a nano-pattern.

Use of the anti-reflection elements can reduce total internal reflection of light travelling from the semiconductor layer to air through the substrate, thereby improving light extraction efficiency. In addition, since the anti-reflection elements are formed in the nano-pattern, the anti-reflection elements can be formed in a moth-eye pattern, thereby significantly reducing reflection at an interface between the substrate and the semiconductor layer.

The anti-reflection element may include a base adjoining the substrate and the nano-pattern formed on the base, and the nano-pattern may include pillars and holes formed between the pillars.

The base may have an index of refraction higher than or equal to that of the substrate.

The nano-pattern may have an index of refraction between those of the substrate and air.

Regions between the pillars or the holes may have a nano-scale width smaller than a wavelength of light generated in an active layer.

The pillars may have a width gradually decreasing away from the base.

The nano-pattern may have an index of refraction gradually decreasing away from the base.

The nano-pattern may be formed of silicon nitride or silicon oxy-nitride having an index of refraction higher than that of the substrate.

The light emitting diode may be a flip-chip type light emitting diode.

In accordance with another aspect of the present invention, a method of fabricating a light emitting diode includes: forming an anti-reflection element having a second index of refraction on one surface of a substrate having a first index of refraction; and growing a gallium nitride semiconductor layer on the other surface of the substrate, wherein the anti-reflection element includes a nano-pattern.

Forming the anti-reflection element may include: forming a dielectric layer on the substrate; and forming the nano-pattern by patterning the dielectric layer.

The anti-reflection layer may further include a base and the nano-pattern may be formed on the base.

Forming the anti-reflection element may further include: forming a metal layer on the dielectric layer; and forming a metallic nano-pattern by heat treating the metal layer.

Forming the anti-reflection element may further include forming the nano-pattern by etching the dielectric layer using the metallic nano-pattern as an etching mask.

The metallic nano-pattern may be removed by etching after the nano-pattern is formed.

The nano-pattern may include pillars and holes formed on the base.

The pillars may have a width gradually decreasing away from the base.

An index of refraction the nano-pattern may gradually decrease away from the base.

The nano-pattern may be formed of silicon nitride or silicon oxy-nitride having an index of refraction higher than that of the substrate.

The light emitting diode may be a flip-chip type light emitting diode.

According to embodiments of the present invention, the anti-reflection element makes it possible to reduce light loss caused by total internal reflection of light travelling from the substrate to air. Accordingly, it is possible to improve light extraction efficiency of a light emitting diode that emits light through a substrate, such as a flip-chip type light emitting diode.

It is to be understood that both the foregoing general description and the following detailed description are exemplary and explanatory and are intended to provide further explanation of the invention as claimed.

### BRIEF DESCRIPTION OF THE DRAWINGS

The above and other aspects, features, and advantages of the present invention will become apparent from the detailed description of the following embodiments in conjunction with the accompanying drawings, in which:

FIG. 1 is a schematic sectional view of a light emitting diode according to one embodiment of the present invention;

FIG. 2A is a detailed plan view of the light emitting diode shown in FIG. 1;

FIG. 2B is a sectional view of the light emitting diode taken along line I-I′ shown in FIG. 2A;

FIG. 3 is an enlarged view of region A shown in FIG. 1 according to one is embodiment of the present invention;

FIG. 4 is an enlarged view of region A shown in FIG. 1 according to another embodiment of the present invention;

FIGS. 5 to 9 are sectional views showing a method of fabricating a light emitting diode according to one embodiment of the present invention;

FIG. 10 is an SEM image showing a metallic nano-pattern; and

FIG. 11 is an SEM image showing a nano-pattern of an anti-reflection element formed using a dielectric layer.

FIG. 12A is a plan view and a sectional view of a light emitting device according to one embodiment of the present invention;

FIG. 12B is a sectional view taken along line A-A of FIG. 12A;

FIG. 13A is a plan view and a sectional view of a light emitting device according to another embodiment of the present invention;

FIG. 13B is a sectional view taken along line A-A of FIG. 13A;

FIG. 14A is a plan view and a sectional view of a light emitting device according to a further embodiment of the present invention;

FIG. 14B is a sectional view taken along line A-A of FIG. 14A;

FIGS. 15 to 17 are sectionals views showing a method of fabricating an upper pattern of the light emitting devices shown in FIGS. 1 to 3, respectively; and

FIGS. 18A, 18B, 19A, 19B, 20A, 20B, 21A, 21B, 22A and 22B are plan views and corresponding sectional views showing a light emitting diode according to an exemplary embodiment of the invention and a method of fabricating the same.

### DETAILED DESCRIPTION OF THE INVENTION

Hereinafter, embodiments of the present invention will be described in detail with reference to the accompanying drawings. The following embodiments are provided by way of examples so as to fully convey the spirit of the present invention to those skilled in the art. Accordingly, the present invention is not limited to the embodiments disclosed herein and may also be implemented in different forms. In the drawings, widths, lengths, thicknesses, and the like of elements may be exaggerated for convenience. Throughout the specification, like reference numerals denote like elements having the same or similar functions.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

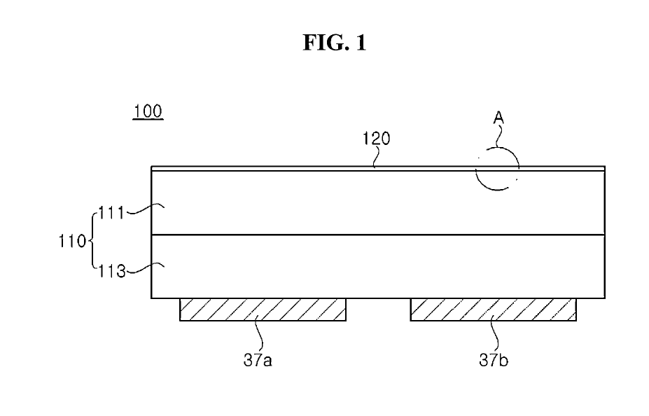

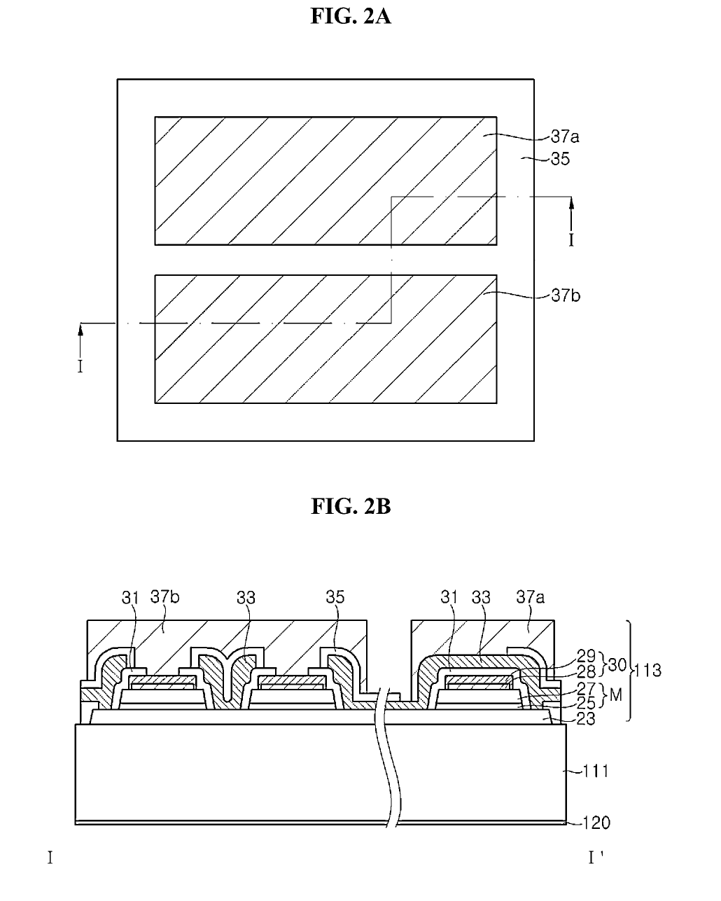

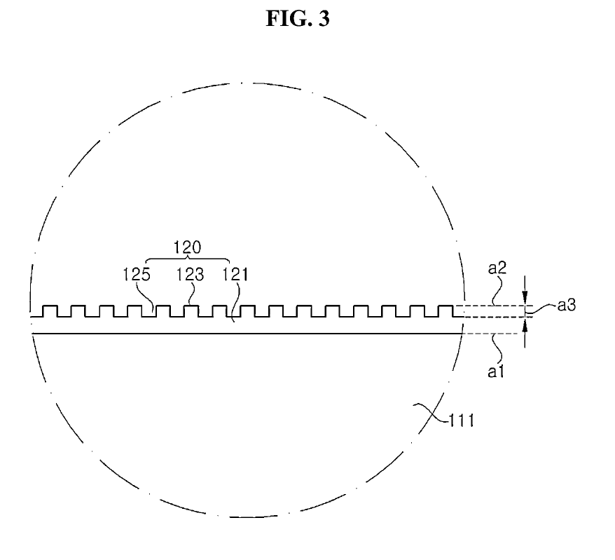

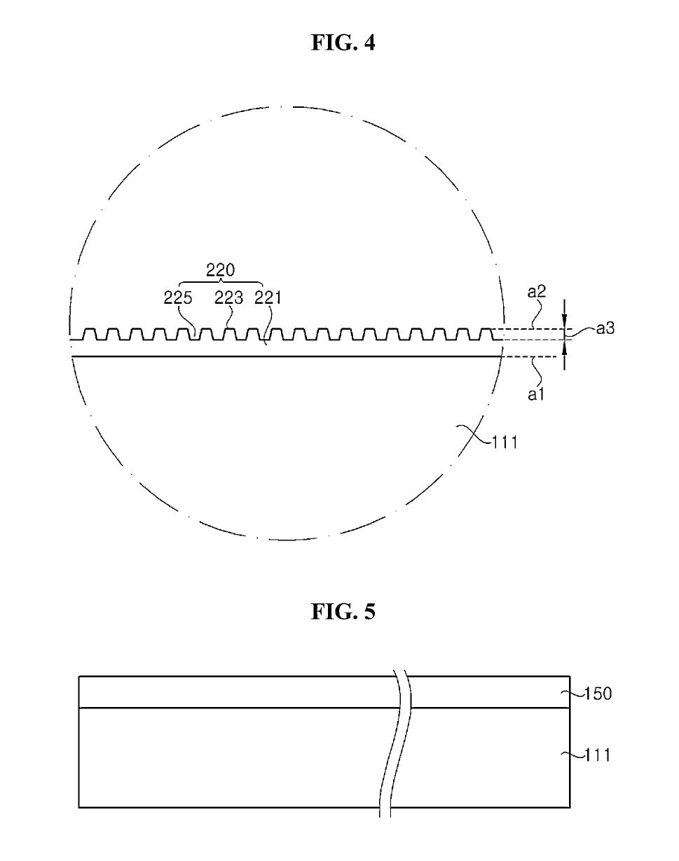

FIG. 1 is a schematic sectional view of a light emitting diode according to one embodiment of the present invention, FIG. 2A is a detailed plan view of the light emitting diode shown in FIG. 1, and FIG. 2B is a sectional view taken along line I-I′ shown in FIG. 2A. FIG. 3 is an enlarged view of region A shown in FIG. 1 according to one embodiment of the present invention.

Referring to FIGS. 1-3, a light emitting diode 100 according to one exemplary embodiment of the invention may include a light emitting diode chip 110 including a substrate 111, a semiconductor stack 113, and electrode pads 37a, 37b.

The semiconductor stack 113 is placed on one surface of the substrate 111, and an anti-reflection element 120 is placed on the other surface of the substrate 111.

The light emitting diode 100 is a flip-chip type light emitting diode in which the electrode pads 37a, 37b are placed on a lower side of the light emitting diode chip 110.

The substrate 111 may be a growth substrate for growing a semiconductor layer, for example, a sapphire substrate or a gallium nitride substrate. For example, the substrate 111 may be a heterogeneous substrate suitable for growing a gallium nitride semiconductor layer and has a first index of refraction. The substrate 111 may be, for example, a sapphire substrate having an index of refraction of about 1.78, or a SiC substrate having an index of refraction of about 2.72 at a wavelength of 450 nm.

The semiconductor stack 113 is placed on one surface of the substrate 111. The semiconductor stack 113 includes a first conductivity-type semiconductor layer 23 placed on the substrate 111 and a plurality of mesas M, and each of the mesas M includes an active layer 25 is and a second conductivity-type semiconductor layer 27. The active layer 25 is interposed between the first conductivity-type semiconductor layer 23 and the second conductivity-type semiconductor layer 27. Reflective electrodes 30 are placed on the mesas M, respectively.

The mesas M may have an elongated shape and extend parallel to each other in one direction, as shown in the drawings. Such a shape simplifies formation of the mesas M having the same shape in a plurality of chip regions on the growth substrate 111.

Although the reflective electrodes 30 may be formed on the respective mesas M, it should be understood that the present invention is not limited thereto. Alternatively, after second conductivity-type semiconductor layer 27 is formed, the reflective electrodes 30 may be formed on the second conductivity-type semiconductor layer 27 before formation of the mesas M. The reflective electrodes 30 cover most of upper surfaces of the mesas M and have substantially the same shape as that of the mesa M in plan view.

The reflective electrodes 30 include a reflective layer 28 and may further include a barrier layer 29. The barrier layer 29 may cover an upper surface and side surfaces of the reflective layer 28. For example, the reflective layer 28 is patterned and then the barrier layer 29 is formed thereon, whereby the barrier layer 29 may be formed to cover the upper surface and the side surfaces of the patterned reflective layer 28. By way of example, the reflective layer 28 may be formed by depositing a layer of Ag or an Ag alloy such as, Ni/Ag, NiZn/Ag, or TiO/Ag, followed by patterning. The barrier layer 29 may be formed of Ni, Cr, Ti, Pt, Rd, Ru, W, Mo, TiW, or combinations thereof, and prevents diffusion or contamination of metallic materials in the reflective layer.

After the mesas M are formed, an edge of the first conductivity-type semiconductor layer 23 may also be etched. As a result, an upper surface of the substrate 111 is may be exposed. A side surface of the first conductivity-type semiconductor layer 23 may also be slanted with respect to a plane of the substrate 111.

The light emitting diode chip further includes a lower insulation layer 31 that covers the mesas M and the first conductivity-type semiconductor layer 23. The lower insulation layer 31 has openings at specific regions thereof to allow electrical connections to the first conductivity-type semiconductor layer 23 and the second conductivity-type semiconductor layer 27. For example, the lower insulation layer 31 may have openings that expose the first conductivity-type semiconductor layer 23 and openings that expose the reflective electrodes 30.

The openings may be placed between the mesas M and near an edge of the substrate 111, and may have an elongated shape extending along the mesas M. On the other hand, some openings are placed on the mesas M and biased towards the same ends of the mesas.

The light emitting diode 100 further includes a current spreading layer 33 formed on the lower insulation layer 31. The current spreading layer 33 covers the mesas M and the first conductivity-type semiconductor layer 23. The current spreading layer 33 has openings placed above the respective mesas M such that the reflective electrodes are exposed therethrough. The current spreading layer 33 may form ohmic contact with the first conductivity-type semiconductor layer 23 through the openings of the lower insulation layer 31. The current spreading layer 33 is insulated from the mesas M and the reflective electrodes 30 by the lower insulation layer 31.

The openings of the current spreading layer 33 have a larger area than those of the lower insulation layer 31, so as to prevent the current spreading layer 33 from contacting the reflective electrodes 30.

The current spreading layer 33 is formed over a substantially all the upper area of is the substrate 21 excluding the openings. Accordingly, current can be easily dispersed through the current spreading layer 33. The current spreading layer 33 may include a highly reflective metal layer, such as an Al layer, and the highly reflective metal layer may be formed on a bonding layer, such as Ti, Cr, Ni or the like. Further, a protective layer having a monolayer or composite layer structure of Ni, Cr or Au may be formed on the highly reflective metal layer. The current spreading layer 33 may have a multilayer structure of, for example, Ti/Al/Ti/Ni/Au.

The light emitting diode 100 further includes an upper insulation layer 35 formed on the current spreading layer 33. The upper insulation layer 35 has openings that expose the reflective electrodes 30 together with openings that expose the current spreading layer 33.

The upper insulation layer 35 may be formed of an oxide insulation layer, a nitride insulation layer, a mixed layer, a alternating stack of such layers, or a polymer such as polyimide, polytetrafluoroethylene (such as Teflon), poly(p-xylylene) (such as Parylene), or the like.

The first pad 37a and the second pad 37b are formed on the upper insulation layer 35. The first pad 37a is connected to the current spreading layer 33 through the openings of the upper insulation layer 35, and the second pad 37b is connected to the reflective electrodes 30 through the openings of the upper insulation layer 35. The first and second pads 37a, 37b may be used as pads for surface mount technology (SMT), connection of bumps for mounting the light emitting diode on the circuit board, and the like.

The first and second pads 37a, 37b may be formed substantially simultaneously by the same process, for example, a photolithography and etching process or a lift-off process. The first and second pads 37a, 37b may include a bonding layer formed of, for example, Ti, Cr, Ni, and the like, and a highly conductive metal layer formed of Al, Cu, Ag, Au, and the like. The is first and second pads 37a, 37b may be formed such that distal ends of the electrode pads are placed on the same plane, whereby the light emitting diode chip can be flip-chip bonded to a conductive pattern formed to the same thickness on the circuit board.

Then, the growth substrate 111 is divided into individual light emitting diode chip units, thereby providing finished light emitting diode chips. The substrate 111 may be removed from the light emitting diode chips before or after division into individual light emitting diode chips.

The anti-reflection element 120 is placed on the other surface of the substrate 111. That is, the anti-reflection element 120 may directly adjoin the substrate 111. The anti-reflection element 120 is interposed between the substrate 111 and air. As shown in FIG. 3, the anti-reflection element 120 is placed at an interface between the substrate 111 and air, and includes a base 121 having a first index of refraction that is higher than that of the substrate 111 and a nano-pattern having a second index of refraction between those of the substrate 111 and the air. The anti-reflection element 120 prevents total internal reflection of light incident from the substrate 111 and improves a difference in index of refraction between the substrate 111 and air due at least in part to the second index of refraction, thereby enhancing light extraction efficiency.

The anti-reflection element 120 includes the base 121 and the nano-pattern. The nano-pattern includes pillars 123 and holes 125. The pillars 123 and the holes 125 may be formed to a nano size. Regions between the pillars 123 or holes 125 have a nano-scale width that is smaller than a wavelength of light generated in the active layer. In addition, the pillars 123 or the holes 125 have a height larger than λ/4 of the light generated in the active layer.

The anti-reflection element 120 has the first index of refraction that is higher than that of the substrate 111 and the second index of refraction that is between those of the substrate 111 and the air. For example, when the substrate 111 is a sapphire substrate, the base 121 may be formed of silicon nitride or silicon oxy-nitride having an index of refraction higher than or equal to that of the sapphire substrate. Accordingly, the anti-reflection element 120 can reduce total internal reflection at a first interface a1 between the substrate 111 and the base 121, thereby improving light extraction efficiency.

The nano-pattern may be formed of silicon nitride or silicon oxy-nitride having an index of refraction higher than or equal to that of the sapphire substrate.

Accordingly, a region a3 where the nano-pattern is formed has an index of refraction between those of the substrate 111 and the air to reduce total internal reflection, thereby improving light extraction efficiency.

According to the embodiment, the substrate 111 is provided on one surface thereof with the semiconductor stack 113 and on the other surface thereof with the anti-reflection element 120, in which the base 121 having the first index of refraction higher than that of the substrate 111 reduces total internal reflection at the first interface a1 between the substrate 111 and the anti-reflection element 120, and the nano-pattern having the second index of refraction between those of the substrate 111 and the air reduces total internal reflection at a second interface a2 between the anti-reflection element 120 and the air, thereby improving light extraction efficiency.

In addition, the light emitting diode is directly bonded to a circuit board by flip-chip bonding and has advantages of high efficiency and small-size, as compared with a general light emitting device of a package-type.

Although the anti-reflection element 120 has been illustrated as being formed using a dielectric layer such as silicon nitride or silicon oxy-nitride in the embodiment, the is present invention is not limited thereto. Alternatively, the anti-reflection element 120 may also be directly formed on the substrate 111 by etching a surface of the substrate 111.

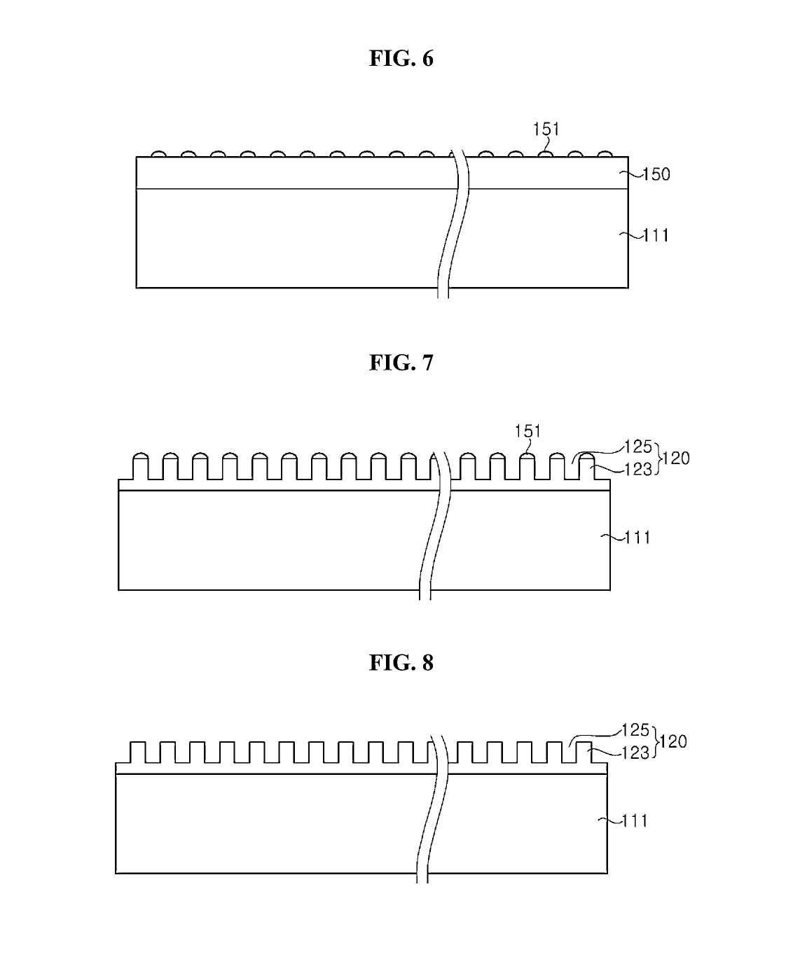

FIG. 4 is an enlarged view of region A shown in FIG. 1, according to another exemplary embodiment of the present invention.

Referring to FIG. 4, in the light emitting diode according to this exemplary embodiment of the invention, an anti-reflection element 220 placed on a substrate 111 may directly adjoin the substrate 111. The anti-reflection element 220 is interposed between the substrate 111 and air. The anti-reflection element 220 is placed at an interface between the substrate 111 and the air, and includes a base 221 having a first index of refraction that is higher than that of the substrate 111, and a nano-pattern having a second index of refraction that is between those of the substrate 111 and the air. The anti-reflection element 220 prevents total internal reflection of light incident from the substrate 111, due to the first index of refraction and reduces a difference in the index of refraction between the substrate 111 and the air, due to the second index of refraction, thereby enhancing light extraction efficiency.

The anti-reflection element 220 includes the base 221 and the nano-pattern. The nano-pattern includes pillars 223 and holes 225 separating the pillars 223. The pillars 223 and the holes 225 may be formed to a nano size. Regions between the pillars 223 or holes 225 have a nano-scale width smaller than a wavelength of light generated in an active layer. In addition, the pillars 223 or the holes 225 have a height larger than a wavelength of the light generated in the active layer.

The anti-reflection element 220 has the first index of refraction that is higher than that of the substrate 111, and the second index of refraction that is between the indexes of refraction of the substrate 111 and the air. For example, when the substrate 111 is a sapphire is substrate, the base 221 may be formed of silicon nitride or silicon oxy-nitride having an index of refraction higher than or equal to that of the sapphire substrate. Accordingly, the anti-reflection element 220 can reduce total internal reflection at a first interface a1 between the substrate 111 and the base 221, thereby improving light extraction efficiency.

The nano-pattern may be formed of silicon nitride or silicon oxy-nitride having an index of refraction higher than or equal to that of the sapphire substrate. Spaces within the nano-pattern, namely, regions between the pillars 123 or at least some of the holes 225 may be filled with a gallium nitride semiconductor layer or may form an air gap.

Particularly, when the spaces within the nano-pattern are filled with the gallium nitride semiconductor layer, the pillars 223 of the nano-pattern may be formed to have a gradually decreasing width, from the bottom to the top thereof. In addition, the nano-pattern may be formed of silicon oxy-nitride having an index of refraction that is the same as or similar to that of the sapphire substrate. In this case, the nano-pattern has an index of refraction that gradually increases from the air to the substrate 111. That is, from a region a3 where the nano-pattern is formed, the nano-pattern has an index of refraction close to the first index of refraction near the substrate 111, and has an index of refraction close to the second index of refraction near the air. As a result, total internal reflection can be reduced at both interfaces of the anti-reflection element 220.

The substrate 111 is provided on one surface thereof with a semiconductor stack (not shown) and on the other surface thereof with the anti-reflection element 220, in which the base 221 having the first index of refraction higher than that of the substrate 111 improves total internal reflection at the first interface a1, between the substrate 111 and the anti-reflection element 220. The nano-pattern having the second index of refraction between those of the is substrate 111 and the air reduces total internal reflection at a second interface a2 between the anti-reflection element 220 and the air, thereby improving light extraction efficiency.

In addition, the light emitting diode is directly bonded to a circuit board by flip-chip bonding and has advantages of high efficiency and small-size, as compared with a general light emitting device of a package-type.

Although the anti-reflection element 220 has been illustrated as being formed using a dielectric layer, such as silicon nitride or silicon oxy-nitride, the present invention is not limited thereto. Alternatively, the anti-reflection element 120 may also be directly formed on the substrate 111 by etching a surface of the substrate 111.

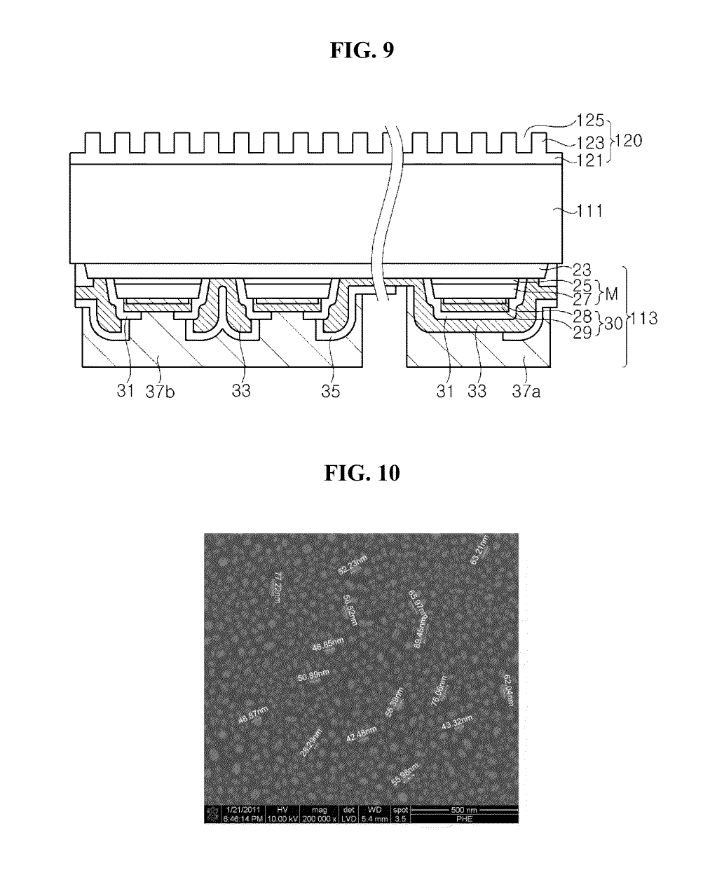

FIGS. 5 to 9 are sectional views showing a method of fabricating a light emitting diode according to one embodiment of the present invention.

Referring to FIG. 5, in the method of fabricating a light emitting diode, first, a dielectric layer 150 is formed on a substrate 111. The substrate 111 may be a sapphire substrate or a SiC substrate. The dielectric layer 150 may be formed of silicon nitride or silicon oxy-nitride using plasma enhanced chemical vapor deposition (PECVD). The dielectric layer 150 may be formed to a thickness larger than a wavelength of light generated in an active layer, for example, a thickness of 500 nm or more.

Next, referring to FIG. 6, a metal layer is formed on the dielectric layer 150 and a metallic nano-pattern 151 is formed by heat treating the metal layer. The metal layer may be formed of, for example, Au, Pt, or Ni to a thickness of 1 nm to 100 nm. In addition, the metal layer may be heat treated at a temperature ranging from 200° C. to 900° C., whereby the metallic material can be aggregated to form the metallic nano-pattern 151.

Next, referring to FIG. 7, an anti-reflection element 120 including a dielectric is nano-pattern is formed by etching the dielectric layer 150 (shown in FIG. 6) using the metallic nano-pattern 151 as a mask. The dielectric layer 150 may be subjected to etching through inductively coupled plasma reactive ion etching (ICPRIE). Accordingly, in the anti-reflection element 120, the dielectric nano-pattern including pillars 123 and holes 125 may be formed.

Next, referring to FIG. 8, the metallic nano-pattern 151 (shown in FIG. 7) is removed from the dielectric nano-pattern. The metallic material may be removed by wet etching.

Upper surfaces of the pillars 123 are exposed by etching the metallic nano-pattern 151 (shown in FIG. 7).

Referring to FIG. 9, the anti-reflection element 120 is formed on one surface of the substrate 111, and a semiconductor stack 113 including a first conductivity-type semiconductor layer 23, an active layer 25 and a second conductivity-type semiconductor layer 27 is grown on the other surface of the substrate 111. The semiconductor stack 113 may be grown by metal organic chemical vapor deposition (MOCVD) or molecular beam epitaxy (MBE).

In the semiconductor stack 113, the first conductivity-type semiconductor layer 23 may be exposed by selectively etching the second conductivity-type semiconductor layer 27 and the active layer 25. A flip-chip type light emitting diode may be fabricated by forming a reflective layer 28, a barrier layer 29, and first and second pads 37a, 37b.

Since the configuration of the semiconductor stack 113 is the same as that shown in FIG. 2, a detailed description thereof will be omitted.

Although the dielectric layer 150 has been illustrated as being subjected to etching using the metallic nano-pattern 151 in the embodiment shown in FIGS. 5 to 9, the dielectric layer 150 may also be subjected to patterning using a scanner or electron-beam lithography equipment.

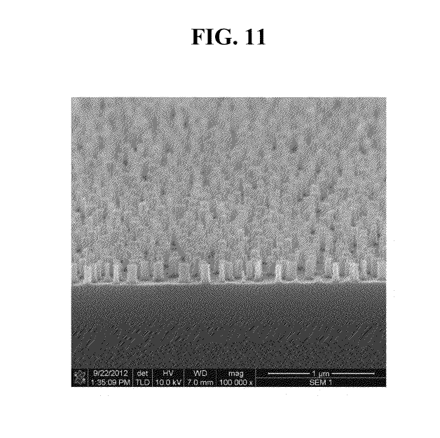

FIG. 10 is a SEM image showing a nano-pattern formed of Ni. It can be seen that Ni aggregates have a size of about 100 nm or less and gaps between the aggregates have a size of 100 nm or less.

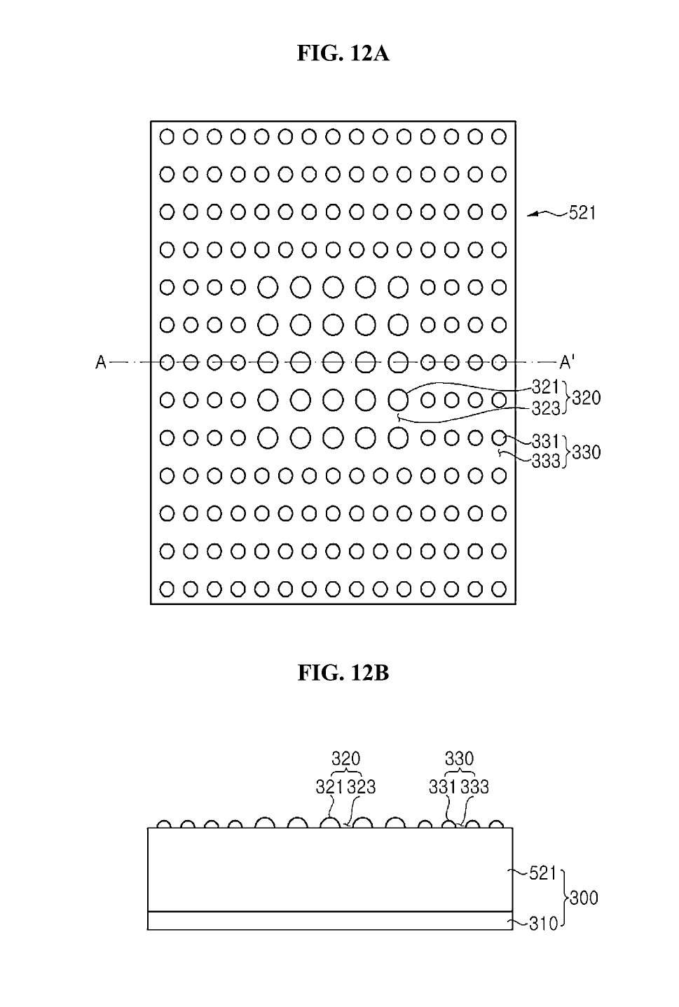

FIG. 11 is an SEM image showing a nano-pattern of an anti-reflection element after removal of a metallic nano-pattern.

As described above, the anti-reflection element 120 or 220 is placed on the substrate 111 to reduce total internal reflection caused by a difference in index of refraction at an interface between the air and the substrate 111, thereby improving light extraction efficiency.

In addition, the light emitting diode is directly bonded to a circuit board by flip-chip bonding, and has advantages of high efficiency and small-size, as compared with a general light emitting device of a package type.

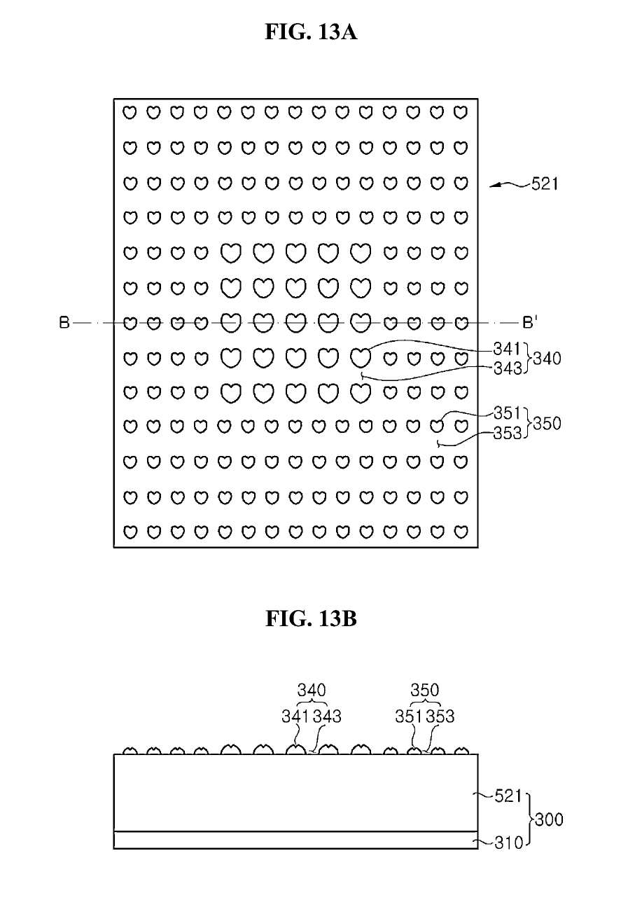

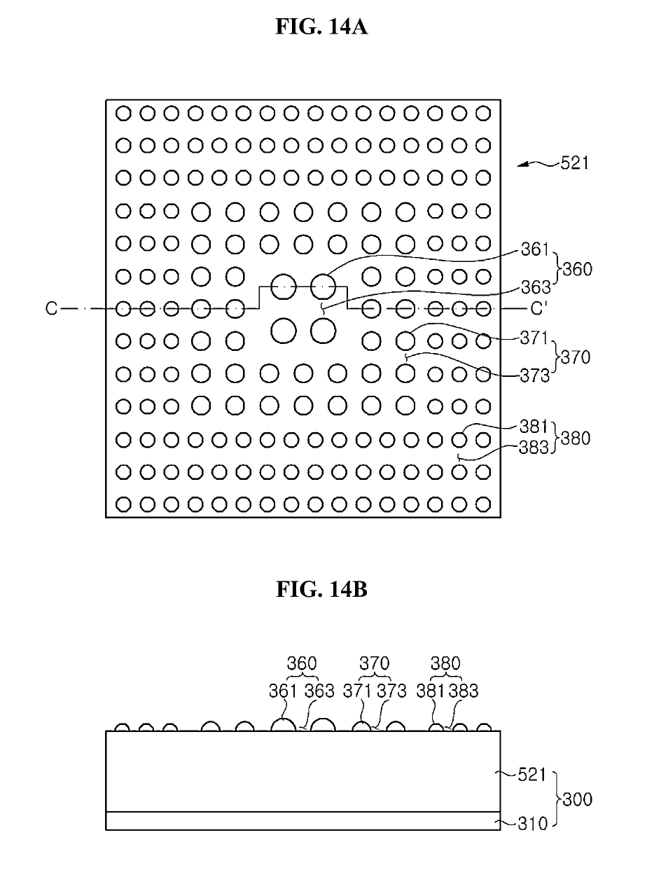

FIG. 12A is a plan view and a sectional view of a light emitting device according to an exemplary embodiment of the present invention. FIG. 12B is a sectional view taken along line A-A′ of FIG. 12A.

Referring to FIGS. 12A and 12B, a light emitting device according to one embodiment of the invention includes a light emitting diode 300 that includes a transparent substrate 521 and a light emitting structure 310.

Any structure capable of emitting light using semiconductor layers may be used as the light emitting structure 310. The light emitting structure 310 may have, for example, a flip-chip structure or a vertical type structure including n-type and p-type semiconductor layers. In addition, the light emitting device may further include first and second electrodes (not shown) formed under the light emitting structure 310 and thus, may be used as a wafer level package without packaging. Particularly, the light emitting structure 310 may emit light having a peak is wavelength in a UV band.

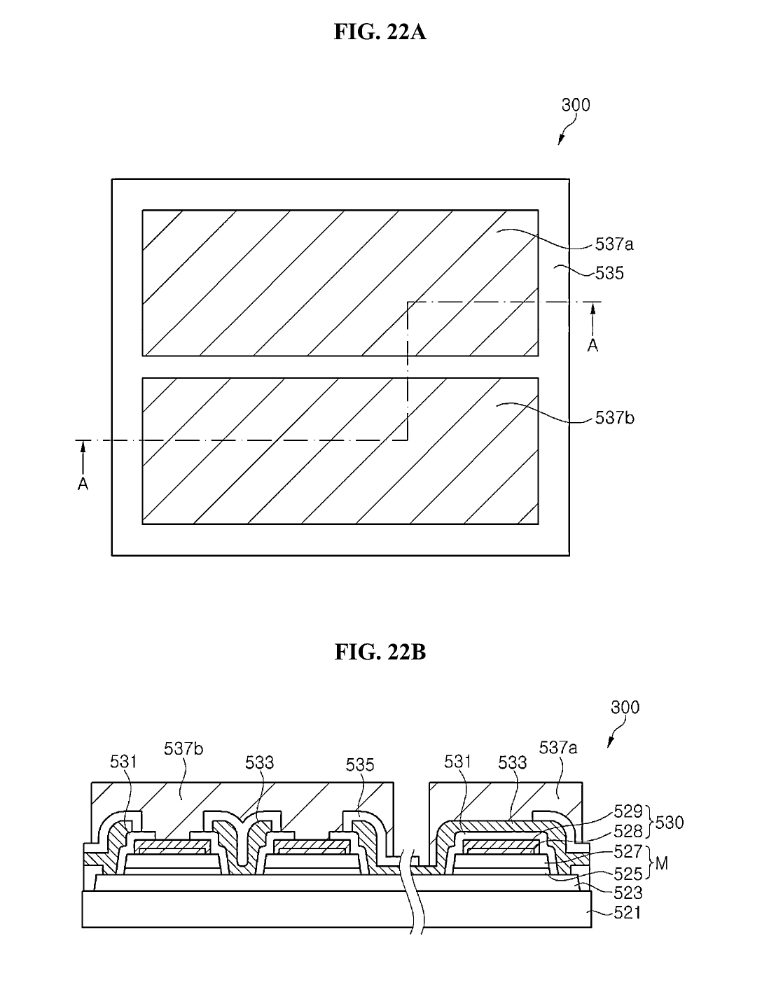

One example of the light emitting diode 300 will now be described with reference to FIGS. 18 to 22. However, it should be understood that the present invention is not limited thereto, and a structure of the light emitting diode 300 which will be described below is provided to aid in comprehension of the invention.

FIGS. 18A to 22B are plan views and sectional views taken along lines A-A of corresponding plan views, showing a light emitting diode 300 according to exemplary embodiments of the invention and a method of fabricating the same.

First, referring to FIG. 18, a first conductivity-type semiconductor layer 523 is formed on a transparent substrate 521, and separated mesas M are formed on the first conductivity-type semiconductor layer 523. Each of the mesas M includes an active layer 525 and a second conductivity-type semiconductor layer 527. The active layer 525 is interposed between the first conductivity-type semiconductor layer 523 and the second conductivity-type semiconductor layer 527. Reflective electrodes 530 are placed on the mesas M, respectively.

The mesas M may be formed by growing an epitaxial layer including the first conductivity-type semiconductor layer 523, the active layer 525, and the second conductivity-type semiconductor layer 527 on the transparent substrate 521, by metal organic chemical vapor deposition (MOCVD), followed by patterning the second conductivity-type semiconductor layer 527 and the active layer 525 to expose the first conductivity-type semiconductor layer 523. Side surfaces of the mesas M may be obliquely formed by photo-resist reflow or other techniques. An inclined profile of the side surfaces of the mesas M enhances light extraction efficiency of the active layer 525.

The mesas M may have an elongated shape and extend parallel to each other in is one direction, as shown in FIG. 16. Such a shape simplifies formation of the mesas M having the same shape in a plurality of chip regions of the transparent substrate 521.

Although the reflective electrodes 530 may be formed on the respective mesas M, it should be understood that the present invention is not limited thereto. Alternatively, after the second conductivity-type semiconductor layer 527 is formed, the reflective electrodes 530 may be formed on the second conductivity-type semiconductor layer 527 before formation of the mesa M. The reflective electrodes 530 cover most of an upper surface of the mesas M and have substantially the same shape as that of the mesas M in plan view.

The reflective electrodes 530 include a reflective layer 28 and may further include a barrier layer 529. The barrier layer 529 may cover an upper surface and side surfaces of the reflective layer 528. For example, the reflective layer 528 is patterned and then the barrier layer 529 is formed thereon, whereby the barrier layer 529 may be formed to cover the upper surface and the side surfaces of the patterned reflective layer 528. By way of example, the reflective layer 528 may be formed by depositing Ag, Ag alloys, Ni/Ag, NiZn/Ag, TiO/Ag, or Pt/Ag, followed by patterning. The barrier layer 529 may be formed of Ni, Cr, Ti, Pt, W, Mo, or a composite layer thereof, and prevents diffusion or contamination of metallic material in the reflective layer.

After the mesas M are formed, an edge of the first conductivity-type semiconductor layer 523 may also be subjected to etching. As a result, an upper surface of the substrate 311 may be exposed. A side surface of the first conductivity-type semiconductor layer 523 may also be inclined with respect to the plane of the substrate 521.

As shown in FIGS. 18A and 18B, the mesas M may be restrictively placed within an upper region of the first conductivity-type semiconductor layer 523. That is, the mesas M may is be placed in an island pattern on the upper region of the first conductivity-type semiconductor layer 523.

Referring to FIGS. 19A and 19B, a lower insulation layer 531 is formed to cover the mesas M and the first conductivity-type semiconductor layer 523. The lower insulation layer 531 has openings 531a, 531b in specific regions thereof to allow electrical connections to the first conductivity-type semiconductor layer 523 and the second conductivity-type semiconductor layer 527. For example, the lower insulation layer 531 may have openings 531a that expose the first conductivity-type semiconductor layer 523 and openings 531b that expose the reflective electrodes 530.

The openings 531a may be placed between the mesas M and near an edge of the substrate 521, and may have an elongated shape extending along the mesas M. In addition, the openings 531b are disposed on the mesas M while being biased towards the same ends of the respective mesas.

The lower insulation layer 531 may be formed of an oxide film of SiO₂, a nitride film of SiNₓ, or an insulation film of MgF₂ by chemical vapor deposition (CVD), electron-beam evaporation, or the like. Although the lower insulation layer 531 is shown as being composed of a single layer, the lower insulation layer 531 may also be composed of multiple layers. In addition, the lower insulation layer 531 may form a distributed Bragg reflector (DBR), in which low and high index of refraction material layers are alternately stacked one above another. For example, an insulation reflective layer having high reflectivity may be formed by stacking SiO₂/TiO₂ or SiO₂/Nb₂O₅ layers.

Referring to FIGS. 20A and 20B, a current spreading layer 533 is formed on the lower insulation layer 531. The current spreading layer 533 covers the mesas M and the first is conductivity-type semiconductor layer 523. The current spreading layer 533 has openings 533a placed above the respective mesas M, such that the reflective electrodes are exposed therethrough. The current spreading layer 533 may form ohmic contact with the first conductivity-type semiconductor layer 523 through the openings 531a of the lower insulation layer 531. The current spreading layer 533 is insulated from the mesas M and the reflective electrodes 530 by the lower insulation layer 531.

The openings 533a of the current spreading layer 533 have a larger area than the openings 531b of the lower insulation layer 531, so as to prevent the current spreading layer 533 from contacting the reflective electrodes 530. Accordingly, sidewalls of the openings 533a are placed on the lower insulation layer 531.

The current spreading layer 533 covers substantially all of an upper area of the substrate 521, excluding areas exposed by the openings. Accordingly, current can be easily dispersed through the current spreading layer 533. The current spreading layer 533 may include a highly reflective metal layer, such as an Al layer, and the highly reflective metal layer may be formed on a bonding layer formed of Ti, Cr, Ni or the like. Further, a protective layer having a monolayer or composite layer structure of Ni, Cr and/or Au layers may be formed on the highly reflective metal layer. The current spreading layer 533 may have a multilayer structure of, for example, of Ti/Al/Ti/Ni/Au layers.

Referring to FIGS. 21A and 21B, an upper insulation layer 535 is formed on the current spreading layer 533. The upper insulation layer 535 has openings 535b that expose the reflective electrodes 530 together with an opening 535a that exposes the current spreading layer 533. The opening 535a may have an elongated shape extending in a direction perpendicular to a longitudinal direction of the mesas M, and may have a larger area than the openings 535b. The is openings 535b expose the portions of the reflective electrodes 530 exposed through the openings 533a of the current spreading layer 533 and the openings 531b of the lower insulation layer 531. The openings 535b may have a smaller area than the openings 533a of the current spreading layer 533 but may have a larger area than the openings 531b of the lower insulation layer 531. Accordingly, sidewalls of the openings 533a of the current spreading layer 533 may be covered with the upper insulation layer 535.

The upper insulation layer 535 may be formed using an oxide insulation layer, a nitride insulation layer, or a polymer such as polyimide, polytetrafluoroethylene (such as Teflon), poly(p-xylylene) (such as Parylene), or the like.

Referring to FIGS. 22A and 22B, a first pad 537a and a second pad 537b are formed on the upper insulation layer 535. The first pad 537a is connected to the current spreading layer 533 through the opening 535a of the upper insulation layer 535, and the second pad 537b is connected to the reflective electrodes 530 through the openings 535b of the upper insulation layer 535. The first and second pads 537a, 537b may be used as pads for the connection of bumps for mounting the light emitting diode on a sub-mount, a package, or a printed circuit board, or pads for surface mount technology (SMT).

The first and second pads 537a, 537b may be formed substantially simultaneously by the same process, for example, a photolithography and etching process or a lift-off process. The first and second pads 537a, 537b may include a bonding layer formed of, for example, Ti, Cr, Ni, and the like, and a high conductivity metal layer formed of Al, Cu, Ag, Au, and the like.

Then, the transparent substrate 521 is divided into individual light emitting diode chip units, thereby providing finished light emitting diode chips. At this time, the transparent substrate 521 may be divided by a scribing method such as laser scribing.

Hereinafter, the structure of the light emitting diode 300 will be described in detail with reference to FIG. 22.

Referring to FIGS. 22A and 22B, the light emitting diode may include the first conductivity-type semiconductor layer 523, the mesas M, the reflective electrodes 530, the current spreading layer 533, the transparent substrate 521, the lower insulation layer 531, the upper insulation layer 535, and the first and second pads 537a, 537b.

The transparent substrate 521 may be a growth substrate for growing gallium nitride epitaxial layers. For example, the transparent substrate 521 may be a sapphire substrate, a silicon carbide substrate, a silicon substrate, or a gallium nitride substrate. In this exemplary embodiment, the transparent substrate 521 may be a sapphire substrate.

The first conductivity-type semiconductor layer 523 is continuous, and the mesas M are placed to be separated from each other on the first conductivity-type semiconductor layer 523. As illustrated with reference to FIG. 12, the mesas M include the active layer 525 and the second conductivity-type semiconductor 527 and have an elongated shape extending toward one side. Here, the mesas M are a stack of gallium nitride compound semiconductor layers. As shown in FIG. 12, the mesas M may be placed on the upper region of the first conductivity-type semiconductor layer 523.

The first conductivity-type semiconductor layer 523, the active layer 525, and the second conductivity-type semiconductor layer 527 may include nitride semiconductors. The first and second conductivity-type semiconductor layers 523, 527 may be n-type and p-type semiconductor layers, respectively, or vice versa. The active layer 525 may include a nitride semiconductor, and a peak wavelength of light emitted from the active layer 525 may be determined by adjusting a composition ratio of the nitride semiconductor. Particularly, in this is embodiment, the active layer 525 may include AlGaN to emit light having a peak wavelength in a UV band.

The reflective electrodes 530 are respectively placed on the mesas M to form ohmic contact with the second conductivity-type semiconductor layer 527. As illustrated with reference to FIGS. 12A and 12B, the reflective electrodes 530 may include the reflective layer 528 and the barrier layer 529, and the barrier layer 529 may cover the upper surface and the side surfaces of the reflective layer 528.

The current spreading layer 533 covers the mesas M and the first conductivity-type semiconductor layer 523. The current spreading layer 533 has the openings 533a placed above the respective mesas M, such that the reflective electrodes 530 are exposed therethrough. The current spreading layer 533 also forms ohmic contact with the first conductivity-type semiconductor layer 523 and is insulated from the mesas M. The current spreading layer 533 may include a reflective metal such as Al.

The current spreading layer 533 may be insulated from the mesas M by the lower insulation layer 531. For example, the lower insulation layer 531 may be interposed between the mesas M and the current spreading layer 533, to insulate the current spreading layer 533 from the mesas M. In addition, the lower insulation layer 531 may have the openings 531b exposing portions of the upper regions of the respective mesas M, such that the reflective electrodes 530 are exposed therethrough, and the openings 531a that expose the first conductivity-type semiconductor layer 523 therethrough. The current spreading layer 533 may be connected to the first conductivity-type semiconductor layer 523 through the openings 531a of the lower insulation layer 531. The openings 531b of the lower insulation layer 531 have a smaller area than the openings 533a of the current spreading layer 533, and are all exposed through the is openings 533a.

The upper insulation layer 535 covers at least a portion of the current spreading layer 533. The upper insulation layer 535 has the openings 535b that expose the reflective electrodes 530. In addition, the upper insulation layer 535 may have the openings 535a that expose the current spreading layer 533. The upper insulation layer 535 may cover the sidewalls of the openings 533a of the current spreading layer 533.

The first pad 537a may be placed on the current spreading layer 533 and, for example, may be connected to the current spreading layer 533 through the opening 535a of the upper insulation layer 535. The second pad 537b is connected to the reflective electrodes 530 exposed through the openings 535b.

The current spreading layer 533 covers the mesas M and almost all of the first conductivity-type semiconductor layers between the mesas M. Thus, the current spreading layer 533 may allow easy dispersion of current therethrough.

In addition, the current spreading layer 523 includes a reflective metal layer such as Al. The lower insulation layer is formed of an insulation reflective layer, so that the current spreading layer 523 or the lower insulation layer 531 can reflect light that is not reflected by the reflective electrodes 530, thereby enhancing light extraction efficiency.

Although the light emitting diode 300 illustrated above may be used in various embodiments of the present invention, the present invention is not limited thereto.

Referring back to FIGS. 12A and 12B, the transparent substrate 521 includes at least two different convex-concave patterns (protrusion patterns) 320, 330. The convex-concave patterns 320, 330 may include a first convex-concave pattern 320 and a second convex-concave pattern 330.

The first and second convex-concave patterns 320, 330 may be formed on an upper surface of the transparent substrate 521. The first convex-concave pattern 320 may include protrusions 321 and depressions 323. The depressions 323 may be in the form of a gap or empty space that separates the protrusions 321. The second convex-concave pattern 330 may also include protrusions 331 and depressions 333. The depressions 333 may be in the form of a gap or empty space that separates the protrusions 331.

As shown in the plan view of FIG. 12A, the first and second convex-concave patterns 320, 330 may be placed in central and peripheral regions of the upper surface of the transparent substrate 321, respectively. Specifically, the upper surface of the transparent substrate 521 may include a first region and a second region, in which the first region may be defined as a region in the middle of the upper surface of the transparent substrate 521 and the second region may be defined as a region enclosing the first region. Accordingly, the first and second convex-concave patterns 320, 330 may be arranged in the first and second regions, respectively.

The protrusions 321 of the first convex-concave pattern 320 may be larger than the protrusions 331 of the second convex-concave pattern 330. For example, as shown in FIG. 12, the protrusions 321, 331 of the first and second convex-concave patterns 320, 330 may be formed in a semispherical shape, and a diameter of the protrusions 321 may be larger than that of the protrusions 331.

As the convex-concave patterns 320, 330 are formed on the upper surface of the transparent substrate 521, it is possible to reduce a ratio of total internal reflection when light output from the light emitting structure 310 is emitted through the upper surface of the light emitting device. Further, the convex-concave patterns 320, 330 may scatter the light emitted is through the upper surface of the transparent substrate 521, whereby the light emitting device can have a wide beam angle and uniform illumination intensity.

In addition, the ratio of total internal reflection of light passing through the first and second regions may be varied depending upon sizes of the convex-concave patterns 320, 330. Specifically, since the protrusions 321 of the first convex-concave pattern 320 are larger than the protrusions 331 of the second convex-concave pattern 330, the ratio of total internal reflection of light passing through the second region may be smaller than that of light passing through the first region. As such, the amount of light emitted through the peripheral region of the upper surface of the transparent substrate 521 is increased, whereby the amount of light directed toward a side surface of the light emitting device is increased. Accordingly, the light emitting device can emit a larger amount of light to the side surface than a conventional light emitting device that emits a significantly larger amount of light in a direction perpendicular to a light emitting surface thereof than in a lateral direction. Accordingly, the present exemplary embodiments achieve a wide beam angle and uniform illumination intensity at all emission angles.

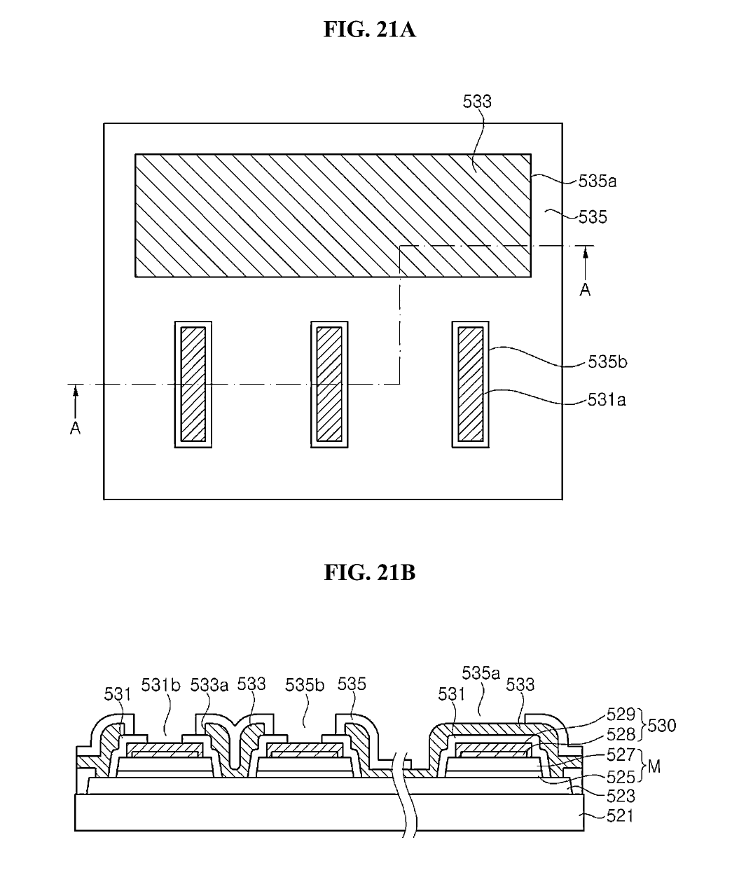

The first and second convex-concave patterns 320, 330 may be formed by photolithography and etching. For example, as shown in FIG. 15, the convex-concave patterns 320, 330 may be formed by forming etching mask patterns 420, 430 on the transparent substrate 521, followed by partially removing the transparent substrate 521 by wet or dry etching. The etching mask patterns may include a first mask pattern 420 and a second mask pattern 430, and the first and second mask patterns 420, 430 may have different shapes of patterns. When the upper surface of the transparent substrate 521 is partially subjected to etching using the etching mask patterns 420, 430 as a mask, the convex-concave patterns 320, 330 may be formed to have is different shapes depending upon the shapes of the etching mask patterns 420, 430 as shown in FIGS. 12A and 12B.

As described above, gaps, sizes, shapes, and the like of the convex-concave patterns 320, 330 may be determined by adjusting the shapes of the etching mask patterns 420, 430. Accordingly, a beam angle of the light emitting device and illumination intensity according to an output angle can be easily controlled simply by adjusting the shapes of the etching mask patterns 420, 430. For example, a fine convex-concave pattern (protrusion pattern) may be formed for a region having a relatively lower illumination intensity, and a coarse convex-concave pattern may be formed for a region having a relatively higher illumination intensity, thereby providing uniform the illumination intensity of the light emitting device.

As shown in FIG. 15, the light emitting device may further include an anti-reflection layer 555 at least partially covering an upper surface and/or side surfaces of the transparent substrate 521. The anti-reflection layer 555 may contain SiO₂. The anti-reflection layer 555 may serve to prevent total internal reflection of light emitted through the transparent substrate 521 and thus, adjust a region constituting the anti-reflection layer 555, thereby determining a beam angle and uniformity of illumination intensity of the light emitting device. For example, when the anti-reflection layer 555 is formed to cover only the side surfaces of the transparent substrate 521, the amount of light emitted to the side surface of the light emitting device can be increased.

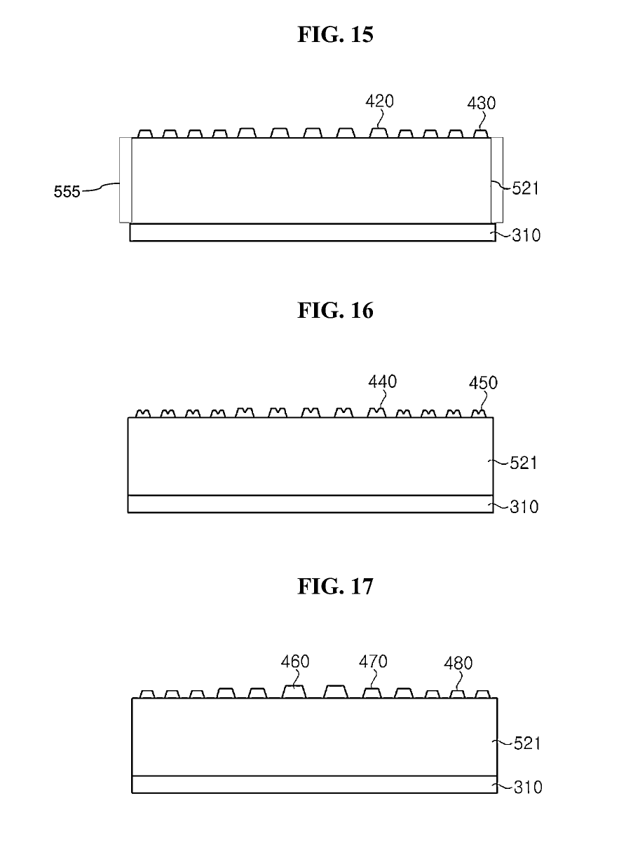

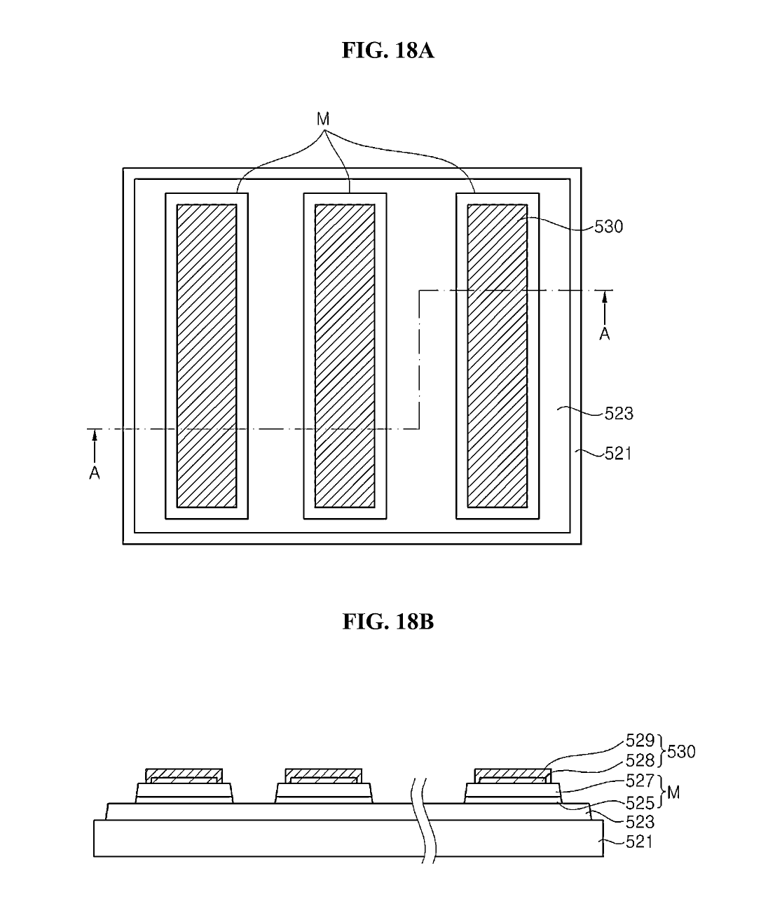

FIG. 13A is a plan view of a light emitting device according to another exemplary embodiment of the present invention. FIG. 13B is a sectional taken along line B-B′ of FIG. 13A.

Although the light emitting device illustrated with reference to FIGS. 13A and 13B is substantially similar to that illustrated with reference to FIGS. 12A and 12B, there is a is difference in the shapes of the convex-concave patterns, which will be described in detail.

The convex-concave patterns (protrusion patterns) include a third convex-concave pattern 340 and a fourth convex-concave pattern 350. The third pattern 340 includes protrusions 341 that are separated by a space 342. The fourth pattern 350 includes protrusions 351 separated by a space 353. The protrusions 341 and 351 may be heart-shaped. The protrusions 341 may be larger than the protrusions and 351.

Since the convex-concave patterns 340, 350 have the heart-shaped protrusions 341 and 351, the light emitting device according to this exemplary embodiment may have higher optical power than the light emitting device having the semispherical convex-concave patterns 320, 330.

The convex-concave patterns 340, 350 shown in FIGS. 13A and 13B may be formed by a method similar to that for the convex-concave patterns 320, 330 shown in FIGS. 12A and 12B. However, as shown in FIG. 16, the convex-concave patterns 340, 350 may be formed using etching mask patterns 440, 450 having a different shape than that in FIG. 15. Specifically, the convex-concave patterns 340, 350 may be provided by forming masking portions of the etching mask patterns 440, 450 in a convex heart shape, followed by partially etching an upper portion of the transparent substrate 521 by dry etching such as reactive ion etching (RIE).

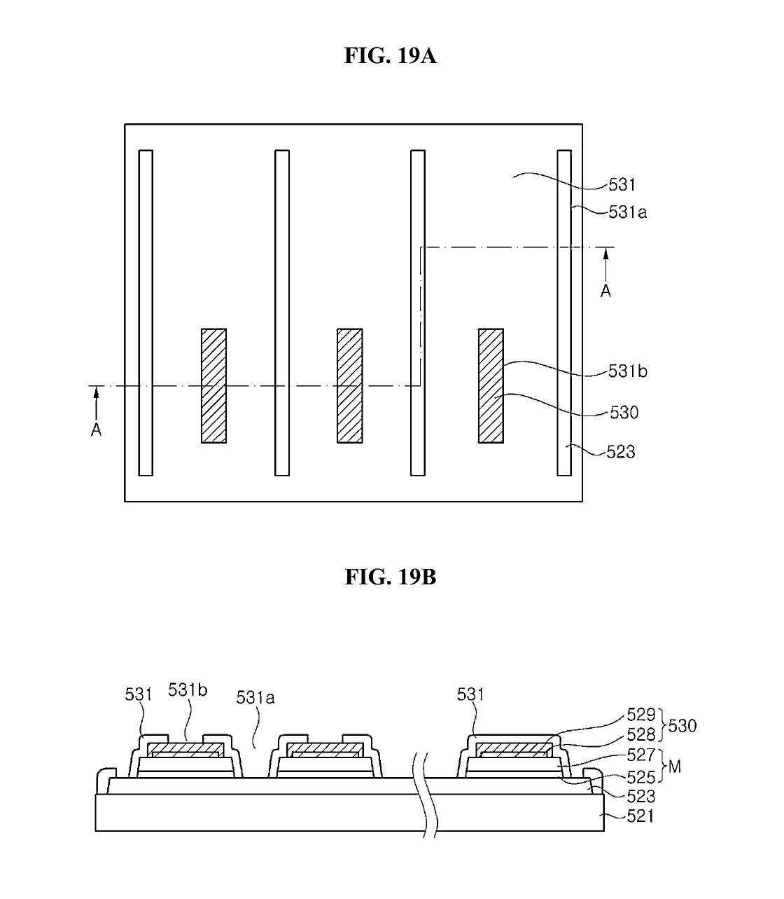

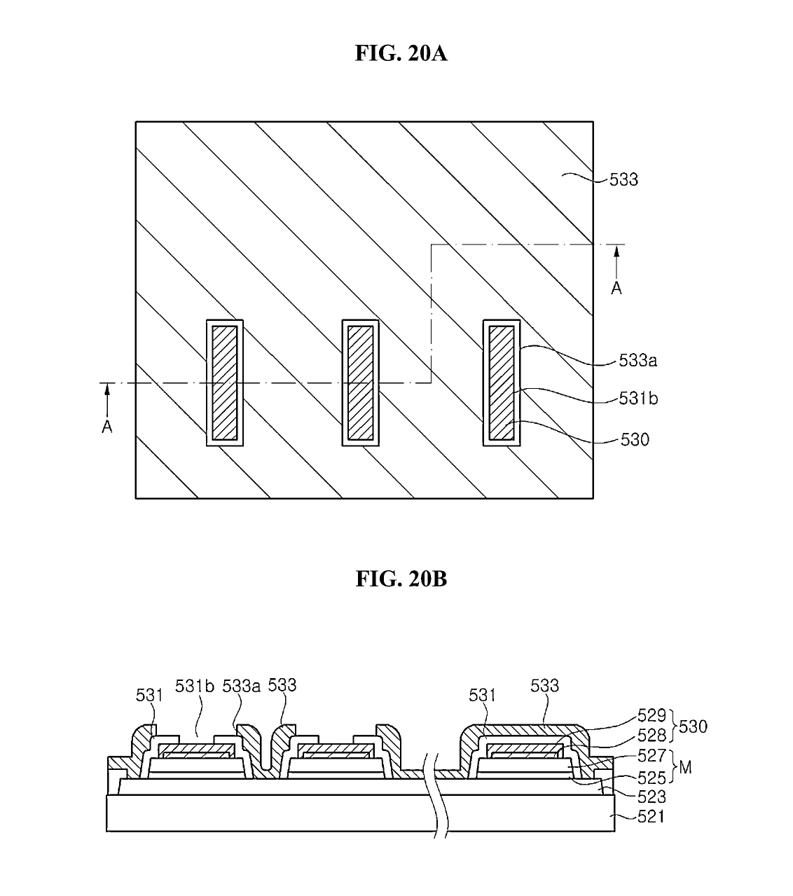

FIG. 14A is a plan view and a sectional view of a light emitting device according to an exemplary embodiment of the present invention. FIG. 14B is a sectional view shows a section taken along line C-C′ of FIG. 14A.

Although the light emitting device illustrated with reference to FIGS. 14A and 14B is substantially similar to that illustrated with reference to FIGS. 12A and 12B, there is a is difference therebetween in that the light emitting device of FIGS. 14A and 14B includes three different types of convex-concave patterns 360, 370, 380. Hereinafter, the difference will be mainly described.

A transparent substrate 521 includes at least three different convex-concave patterns (protrusion patterns). The convex-concave patterns 360, 370, 380 may include a fifth convex-concave pattern 360, a sixth convex-concave pattern 370, and a seventh convex-concave pattern 370.

The fifth to seventh convex-concave patterns 360, 370, 380 may be formed on an upper surface of the transparent substrate 521. The fifth convex-concave pattern 360 may include protrusions 361 and depressions 363, the sixth convex-concave pattern 370 may include protrusions 371 and depressions 373, and the seventh convex-concave pattern 380 may include protrusions 381 and depressions 383.

As shown in the plan view of FIG. 14A, the fifth and seventh convex-concave patterns 360, 380 may be placed in central and peripheral regions of the upper surface of the transparent substrate 321, respectively. The sixth convex-concave pattern 370 may be interposed between the fifth and seventh convex-concave patterns 360, 380. Specifically, the upper surface of the transparent substrate 521 may include a first region, a second region, and a third region, wherein the first region may be defined as a region in the middle of the upper surface of the transparent substrate 521, the second region may be defined as a region enclosing the first region, and the third region may be defined as a region enclosing the second region. The fifth to seventh convex-concave patterns 360, 370, 380 may be arranged in the first to third regions, respectively.

The protrusions 361 of the fifth convex-concave pattern 360 may be larger than is the protrusions 371 of the sixth convex-concave pattern 370, and the protrusions 371 of the sixth convex-concave pattern 370 may be larger than the protrusions 381 of the seventh convex-concave pattern 380. That is, in the light emitting device according to this embodiment, the convex-concave patterns 360, 370, 380 may be formed to have a gradually decreasing size from the central region to the peripheral region on the upper surface of the transparent substrate 521. Accordingly, the amount of light emitted to a side of the light emitting device can be more effectively increased. In addition, it is possible to more easily adjust a beam angle and illumination intensity by forming the convex-concave patterns 360, 370, 380 in various ways, as compared with those of the light emitting device shown in FIGS. 12A and 12B.

The fifth to seventh convex-concave patterns 360, 370, 380 may be formed using etching mask patterns 460, 470, 480 shown in FIG. 17. Since a fabrication method is substantially similar to that illustrated with reference to FIG. 15, a specific description thereof will be omitted.

Although it has been illustrated in the exemplary embodiments that the transparent substrate 21 has two or three different convex-concave patterns, it should be understood that the present invention is not limited thereto. In contrast, a light emitting device having four or more different types of convex-concave patterns is also within the scope of the present invention. In addition, although the convex-concave patterns are illustrated as being continuously formed on the predetermined regions, the convex-concave patterns may also be formed as convex-concave pattern groups separated from each other on a plurality of regions.

Further, although the convex-concave patterns have been illustrated as having the semispherical shape or the convex heart shape in the embodiments illustrated with reference to FIGS. 12A to 17, the convex-concave patterns may have a variety of shapes. For example, the is convex-concave patterns may have at least one of a spherical shape, a conical shape, a frusto-conical shape, and a convex heart shape. Further, the shapes and patterns can be mixed.

In addition, although it has been illustrated in the embodiments that one light emitting device includes convex-concave patterns having different sizes and the same shape, various types of convex-concave patterns may be formed in one light emitting device.

Various modifications and variations can be made to the embodiments without departing from the spirit and scope of the appended claims of the present invention, and the present invention incorporates all of the spirit and scope of the appended claims.

What is claimed is:

1. A light emitting diode comprising:
a substrate having opposing first and second surfaces;
a semiconductor layer disposed on the first surface of the substrate; and
an anti-reflection element disposed on the second surface of the substrate and comprising a nano-pattern.

2. The light emitting diode of claim 1, wherein the anti-reflection element comprises:
a base disposed on the substrate; and
pillars extending from the base and spaced apart from one another, the pillars at least partially forming the nano-pattern.

3. The light emitting diode of claim 2, wherein the base has an index of refraction that is greater than or equal to that of the substrate.

4. The light emitting diode of claim 1, wherein the nano-pattern has an index of refraction that is between an index of refraction of the substrate and an index of refraction of air adjacent to the substrate.

5. The light emitting diode of claim 2, wherein distances between the pillars are smaller than a wavelength of light generated by the semiconductor layer.

6. The light emitting diode of claim 2, wherein widths of the pillars decreases as a distance from the base increases.

7. The light emitting diode of claim 6, wherein an index of refraction of the nano-pattern gradually decreases as a distance from the base increases.

8. The light emitting diode of claim 1, wherein the nano-pattern comprises silicon nitride or silicon oxy-nitride and has an index of refraction that is greater than an index of refraction of the substrate.

9. The light emitting diode of claim 1, wherein the light emitting diode is a flip-chip type light emitting diode.

10. A light emitting device comprising:
a light emitting structure; and
a transparent substrate comprising a first surface, an opposing second surface, a pattern of first protrusions disposed on a central region the first surface, and a pattern of second protrusions disposed on a peripheral region of the first surface, the first protrusions being larger than the second protrusions; and
a light emitting structure disposed on the second surface of the substrate.

11. The light emitting device of claim 10, wherein the pattern of second protrusions surrounds the pattern of first protrusions

12. The light emitting device of claim 10, wherein at least some of the first second protrusions have different shapes.

13. The light emitting device of claim 10, wherein the first and second protrusions have the same shape.

14. The light emitting device of claim 12 wherein the first and second protrusions have shapes independently selected from a semispherical shape, a conical shape, a frusto-conical shape, and a convex heart shape.

15. The light emitting device of claim 4, wherein the first and second protrusions have shapes independently selected from a semispherical shape, a conical shape, a frusto-conical shape, and a convex heart shape.

16. The light emitting device of claim 10, further comprising a pattern of third protrusions disposed on the first surface of the substrate, the third protrusions being smaller than the second protrusions.

17. The light emitting device of claim 16, wherein:
the second protrusions surround the first protrusions; and
the third protrusions surround the second protrusions.

18. The light emitting device of claim 10, wherein the transparent substrate comprises a sapphire substrate.

19. The light emitting device of claim 10, further comprising first and second electrodes disposed on the light emitting structure.

20. The light emitting device of claim 10, further comprising an anti-reflection layer covering a side surface of the transparent substrate.

21. The light emitting device of claim 10, wherein the light emitting structure emits light having a peak wavelength in a UV band.

22. The light emitting diode of claim 10, wherein the light emitting structure comprises:
a first conductivity-type semiconductor layer;
mesas disposed spaced apart from each other on the first conductivity-type semiconductor layer, each of the mesas comprising an active layer and a second conductivity-type semiconductor layer;
reflective electrodes disposed on each of the mesas and in ohmic contact with the corresponding second conductivity-type semiconductor layers; and
a current spreading layer disposed on the mesas, in ohmic contact with the first conductivity-type semiconductor layer, and insulated from the mesas, the current spreading layer comprising openings that respectively face the reflective electrodes and being insulated from the mesas.

23. The light emitting device of claim 22, wherein:
the mesas extend lengthwise in parallel to each other; and
the openings of the current spreading layer are biased towards the same ends of the mesas.

24. The light emitting device of claim 22, further comprising:
an upper insulation layer disposed on the current spreading layer and comprising openings that face the reflective electrodes; and
a second electrode pad disposed on the upper insulation layer and connected to the reflective electrodes through the openings of the upper insulation layer.

25. The light emitting device of claim 24, further comprising a first electrode pad connected to the current spreading layer.
